(19) United States
(12) Patent Application Publication
(10) Pub. No.: US 2012/0103398 A1
(43) Pub. Date: May 3, 2012

(54) SURFACE-TREATED SUBSTRATE, LIGHT-RECEIVING-SIDE PROTECTIVE SHEET FOR SOLAR CELL USING THE SAME, AND SOLAR CELL MODULE

(75) Inventors: Tatsuo Kanou, Sakura-shi (JP); Yasuhiro Takada, Sakura-shi (JP); Shinichi Kudo, Sakura-shi (JP); Takashi Yasumura, Sakura-shi (JP)

(73) Assignee: DIC Corporation, Tokyo (JP)

(21) Appl. No.: 13/318,545

(22) PCT Filed: May 19, 2010
(86) PCT No.: PCT/JP2010/058409

§ 371 Date: Jan. 20, 2012

(30) Foreign Application Priority Data
May 29, 2009 (JP) 2009-130414
Mar. 12, 2010 (JP) 2010-055850

(51) Int. Cl. H01L 31/048; C23C 16/00; C09D 183/04

(52) U.S. Cl. 136/251; 524/547; 427/248.1

(57) ABSTRACT

There is provided a surface-treated substrate obtained by forming a cured material layer composed of a resin composition on a surface of a substrate and then treating a surface of the cured material layer composed of the resin composition with a sulfur trioxide-containing gas, wherein the resin composition contains a composite resin (A) obtained by bonding a polysiloxane segment (a1) having a structural unit represented by general formula (1) and/or general formula (2) and a silanol group and/or a hydrolyzable silyl group to a vinyl-based polymer segment (a2) through a bond represented by general formula (3). There are also provided a light-receiving-side protective sheet for solar cells that uses the surface-treated substrate having a sheet shape and a solar cell module. The surface-treated substrate has good long-lasting antifouling properties.

### TECHNICAL FIELD

The present invention relates to a surface-treated substrate obtained by bringing a sulfur trioxide-containing gas into contact with the surface of a resin composition formed on a substrate, and to a light-receiving-side protective sheet for solar cells that uses the surface-treated substrate having a sheet shape and a solar cell module.

### BACKGROUND ART

Methods for coating, with a certain resin composition layer, the surfaces of various substrates composed of a metal, cement, glass, plastic, wood, paper, and the like are industrially widely utilized as methods for imparting durability, mechanical properties, and functionality to the surfaces of substrates. When these substrates are used as a component of various building components, transport machines such as automobiles, consumer electrical appliances, and other industrial products, secondary processing is often performed, e.g., a forming process is performed by applying heat or pressure or such substrates are bonded to each other with an adhesive or the like, after various properties have been imparted to the surfaces of the substrates by coating or the like. Therefore, these substrates need to have properties for each of the processes.

When these substrates are used as an outdoor component such as an exterior building component or an exterior component for automobiles or as a solar cell component that has been recently developed, long-term use in the open air is required. Thus, these substrates need to have surface properties such as high weather resistance and scratch resistance and a good antifouling property.

On the other hand, when these substrates are used as an interior component, they need to have surface properties suitable for each environment. For example, a component for a kitchen or a bathroom that often becomes dirty needs to have a good antifouling property and high scratch resistance.

A method in which the surface of a component is hydrophilized is known as a method for imparting an antifouling property among the surface properties. Examined examples of a method for hydrophilizing a surface include surface treatment with an acid or alkali compound, ultraviolet treatment, plasma, ozone treatment, and formation of a hydrophilic resin film. It is known that gas phase sulfonation that uses sulfur trioxide gas, which is an acid, can be easily controlled and provide products with high quality (e.g., refer to PTLs 1 and 2). This method is known to be effective for resins having an aryl group such as a polystyrene resin and a polyphenylene sulfide resin. This method is also known to be effective for an olefin resin, a vinyl ester resin, an epoxy resin, and the like.

However, an exterior component subjected to sulfonation using such a resin has a problem in that the durability for the treated surface is poor. In the case where the component is used as a sheet for decorative molding, secondary processing with heat or pressure is performed, that is, heat or pressure is applied after the sulfonation, which may cause cracking.

A polysiloxane-based resin is known as a resin having high weather resistance, solvent resistance, and heat resistance (e.g., refer to PTLs 3 and 4). There is also known a method for imparting hydrophilicity to a component composed of a polysiloxane-based resin through surface reforming (refer to PTLs 5 and 6). However, PTLs 3 and 4 disclose, as a method for imparting hydrophilicity, only a method for introducing a hydrophilic group such as an anionic group, a cationic group, and a nonionic group onto the resin described therein (e.g., refer to paragraphs 0086 and 0087 of PTL 4). PTLs 5 and 6 disclose only a method for imparting hydrophilicity through corona discharge treatment, plasma discharge treatment, or ultraviolet treatment (PTL 5) or through treatment with hot water having a temperature of 50° C. or higher or water vapor (PTL 6). In other words, a method for imparting hydrophilicity through sulfonation is not known.

### CITATION LIST

### Patent Literature

PTL 1: Japanese Unexamined Patent Application Publication No. 63-77946
PTL 2: Japanese Unexamined Patent Application Publication No. 2008-179712
PTL 3: International Publication No. 96/035755 Pamphlet
PTL 4: Japanese Unexamined Patent Application Publication No. 2006-328354
PTL 5: Japanese Unexamined Patent Application Publication No. 2000-109580
PTL 6: Japanese Unexamined Patent Application Publication No. 2000-129209

### SUMMARY OF INVENTION

### Technical Problem

An object of the present invention is to provide a method for imparting surface properties such as a good antifouling property and high durability of the antifouling property, a substrate to which the surface properties have been imparted, and a light-receiving-side protective sheet for solar cells and a solar cell module that use the surface-treated substrate having a sheet shape.

### Solution to Problem

As a result of extensive studies, the inventors of the present invention have found that the object of the present invention can be achieved by forming a cured material layer composed of a polysiloxane resin having a certain siloxane bond on a surface of a substrate and by bringing a sulfur trioxide-containing gas into contact with the cured material layer.

That is, the present invention provides a surface-treated substrate obtained by forming a cured material layer composed of a resin composition on a surface of a substrate and then treating a surface of the cured material layer composed of the resin composition with a sulfur trioxide-containing gas,

wherein the resin composition contains a composite resin (A) obtained by bonding a polysiloxane segment (a1) having a structural unit represented by general formula (1) and/or general formula (2) and a silanol group and/or a hydrolyzable silyl group to a vinyl-based polymer segment (a2) through a bond represented by general formula (3).

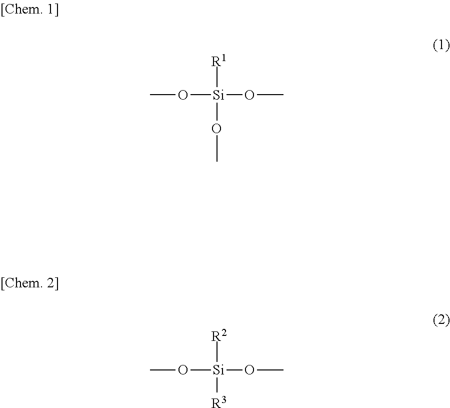

(In the general formulas (1) and (2), R¹, R², and R³ are each independently a group having a polymerizable double bond selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms.)

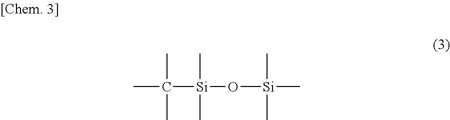

(In the general formula (3), a carbon atom constitutes a part of the vinyl-based polymer segment (a2) and a silicon atom bonded to only an oxygen atom constitutes a part of the polysiloxane segment (a1)).

The present invention also provides a light-receiving-side protective sheet for solar cells obtained by forming a cured material layer composed of a resin composition on a surface of a sheet-shaped substrate and then treating a surface of the cured material layer composed of the resin composition with a sulfur trioxide-containing gas, wherein the resin composition contains a composite resin (A) obtained by bonding a polysiloxane segment (a1) having a structural unit represented by general formula (1) and/or general formula (2) and a silanol group and/or a hydrolyzable silyl group to a vinyl-based polymer segment (a2) through a bond represented by general formula (3).

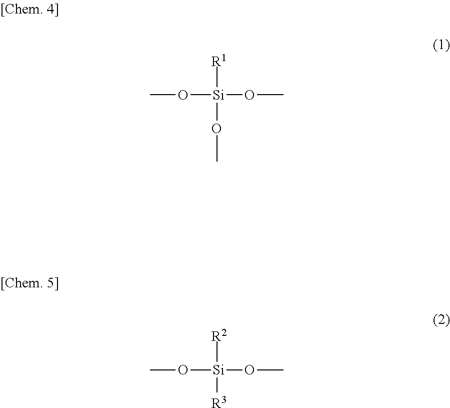

(In the general formulas (1) and (2), R¹, R², and R³ are each independently a group having a polymerizable double bond selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms.)

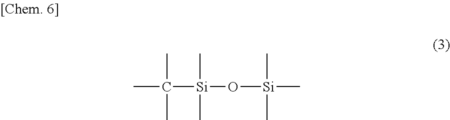

(In the general formula (3), a carbon atom constitutes a part of the vinyl-based polymer segment (a2) and a silicon atom bonded to only an oxygen atom constitutes a part of the polysiloxane segment (a1).)

The present invention also provides a solar cell module including the light-receiving-side protective sheet for solar cells, wherein the light-receiving-side protective sheet for solar cells is disposed on a front surface on a light-receiving side of the solar cell module so that the cured material layer is an outermost surface layer.

The present invention also provides a method for surface-treating a substrate including:

a step (1) of forming, on a surface of a substrate, a cured material layer composed of a resin composition containing a composite resin (A), the composite resin (A) being obtained by bonding a polysiloxane segment (a1) having a structural unit represented by general formula (1) and/or general formula (2) and a silanol group and/or a hydrolyzable silyl group to a vinyl-based polymer segment (a2) through a bond represented by general formula (3); and

a step (2) of bringing a sulfur trioxide-containing gas into contact with the cured material layer composed of the resin composition.

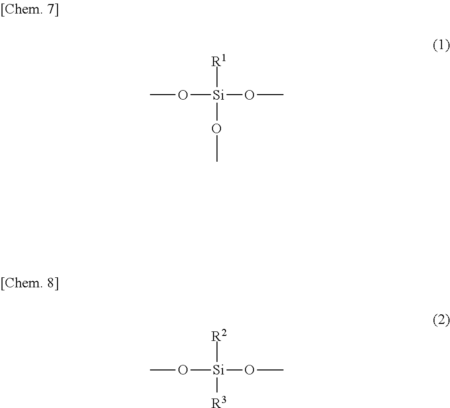

(In the general formulas (1) and (2), R¹, R², and R³ are each independently a group having a polymerizable double bond selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms.)

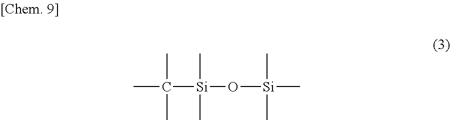

(In the general formula (3), a carbon atom constitutes a part of the vinyl-based polymer segment (a2) and a silicon atom bonded to only an oxygen atom constitutes a part of the polysiloxane segment (a1).)

### Advantageous Effects of Invention

According to the present invention, there can be provided a method for imparting surface properties such as high scratch resistance and a good antifouling property and a substrate to which the surface properties have been imparted.

In the present invention, since the composite resin (A) has a bond represented by the general formula (3), the film obtained has particularly high alkali resistance.

By using the composite resin (A) and a crosslinking monomer such as isocyanate or an acrylic monomer together, the crosslinking density is increased and surface properties such as higher scratch resistance can be achieved.

The presence of an aryl group in the resin composition can further increase the effect achieved by sulfonation and surface properties such as a better antifouling property can be achieved. In particular when any one of R¹, R², and R³ in the general formula (1) of the composite resin (A) is an aryl group, that is, when an aryl group is directly bonded to a silicon atom, the resin composition is not easily decomposed during sulfonation and an antifouling property is achieved in a stable manner.

By using the surface-treated substrate having a sheet shape as the light-receiving-side protective sheet for solar cells, a solar cell module having high weather resistance and a good antifouling property can be obtained.

### DESCRIPTION OF EMBODIMENTS

A surface-treated substrate of the present invention can be obtained through a step (1) of forming, on the surface of the substrate, a cured material layer composed of a resin composition containing the above-described composite resin (A) and a step (2) of bringing a sulfur trioxide-containing gas into contact with the cured material layer composed of the resin composition.

### (Resin Composition: Composite Resin (A))

The composite resin (A) used in the present invention is obtained by bonding a polysiloxane segment (a1) having a structural unit represented by the general formula (1) and/or the general formula (2) and a silanol group and/or a hydrolyzable silyl group (hereinafter simply referred to as polysiloxane segment (a1)) to a vinyl-based polymer segment (a2) having an alcoholic hydroxyl group (hereinafter simply referred to as vinyl-based polymer segment (a2)) through a bond represented by the general formula (3).

A silanol group and/or a hydrolyzable silyl group in the polysiloxane segment (a1) described below and a silanol group and/or a hydrolyzable silyl group in the vinyl-based polymer segment (a2) described below are bonded to each other through a dehydration-condensation reaction to form a bond represented by the general formula (3). Thus, in the general formula (3), a carbon atom constitutes a part of the vinyl-based polymer segment (a2) and a silicon atom bonded to only an oxygen atom constitutes a part of the polysiloxane segment (a1).

The composite resin (A) has, for example, a graft structure in which the polysiloxane segment (a1) is chemically bonded as a side chain of the polymer segment (a2) or a block structure in which the polymer segment (a2) and the polysiloxane segment (a1) are chemically bonded to each other.

(Composite Resin (A): Polysiloxane Segment (a1))

The polysiloxane segment (a1) according to the present invention is a segment having a structural unit represented by general formula (1) and/or general formula (2) and a silanol group and/or a hydrolyzable silyl group.

(Structural Unit Represented by General Formula (1) and/or General Formula (2))

Specifically, R¹, R², and R³ in the general formulas (1) and (2) are each independently a group having a polymerizable double bond selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms.

Examples of the alkylene group having 1 to 6 carbon atoms in the R⁴ include a methylene group, an ethylene group, a propylene group, an isopropylene group, a butylene group, an isobutylene group, a sec-butylene group, a tert-butylene group, a pentylene group, an isopentylene group, a neopentylene group, a tert-pentylene group, a 1-methylbutylene group, a 2-methylbutylene group, 1,2-dimethylpropylene group, a 1-ethylpropylene group, a hexylene group, an isohexylene group, a 1-methylpentylene group, a 2-methylpentylene group, a 3-methylpentylene group, a 1,1-dimethylbutylene group, a 1,2-dimethylbutylene group, a 2,2-dimethylbutylene group, a 1-ethylbutylene group, a 1,1,2-trimethylpropylene group, a 1,2,2-trimethylpropylene group, a 1-ethyl-2-methylpropylene group, and a 1-ethyl-1-methylpropylene group. In view of the availability of a material, R⁴ is preferably a single bond or an alkylene group having 2 to 4 carbon atoms.

Examples of the alkyl group having 1 to 6 carbon atoms include a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a 1-methylbutyl group, a 2-methylbutyl group, a 1,2-dimethylpropyl group, a 1-ethylpropyl group, a hexyl group, an isohexyl group, a 1-methylpentyl group, a 2-methylpentyl group, a 3-methylpentyl group, a 1,1-dimethylbutyl group, a 1,2-dimethylbutyl group, a 2,2-dimethylbutyl group, a 1-ethylbutyl group, a 1,1,2-trimethylpropyl group, a 1,2,2-trimethylpropyl group, a 1-ethyl-2-methylpropyl group, and a 1-ethyl-1-methylpropyl group.

Examples of the cycloalkyl group having 3 to 8 carbon atoms include a cyclopropyl group, a cyclobutyl group, a cyclopentyl group, and a cyclohexyl group.

Examples of the aryl group include a phenyl group, a naphthyl group, a 2-methylphenyl group, a 3-methylphenyl group, a 4-methylphenyl group, a 4-vinylphenyl group, and a 3-isopropylphenyl group.

Examples of the aralkyl group having 7 to 12 carbon atoms include a benzyl group, a diphenylmethyl group, and a naphthylmethyl group.

In the present invention, when at least one of R¹, R², and R³ is the aryl group, that is, when an aryl group is directly bonded to a silicon atom, decomposition during sulfonation does not easily occur and thus an antifouling property is favorably achieved in a stable manner. An aryl group is highly effective for sulfonation. Furthermore, since such an aryl group is directly bonded to a silicon atom, decomposition during sulfonation and desulfonation after the sulfonation do not easily occur. Therefore, the degradation of a film exterior caused by decomposition is suppressed, and the hydrophilic ability lasts for a long time.

The specific meaning in which at least one of R¹, R², and R³ is the aryl group is as follows. When the polysiloxane segment (a1) has only the structural unit represented by the general formula (1), R¹ is the aryl group. When the polysiloxane segment (a1) has only the structural unit represented by the general formula (2), R² and/or R³ is the aryl group. When the polysiloxane segment (a1) has both the structural units represented by the general formulas (1) and (2), at least one of R¹, R², and R³ is the aryl group.

When at least one of R¹, R², and R³ is the group having a polymerizable double bond, curing can be performed with active energy rays or the like. Through two curing mechanisms including the active energy rays and the condensation reaction of a silanol group and/or a hydrolyzable silyl group that achieves an improvement in the crosslinking density of a film, a cured film having higher scratch resistance, acid resistance, alkali resistance, and solvent resistance can be formed. Thus, such a composite resin can be favorably used for substrates that cannot be composed of a thermosetting resin composition and substrates that are easily thermally deformed, such as building exterior paints and plastics. The number of the group having a polymerizable double bond in the polysiloxane segment (a1) is preferably 2 or more, more preferably 3 to 200, and further preferably 3 to 50, which provide a film having even higher scratch resistance. Specifically, when the ratio of polymerizable double bonds in the polysiloxane segment (a1) is 3 to 35% by weight, desired wear resistance can be achieved. Herein, a polymerizable double bond is a general term of a group such as a vinyl group, a vinylidene group, or a vinylene group that can perform a propagation reaction with free radicals. The ratio of polymerizable double bonds indicates percent by weight of the vinyl group, the vinylidene group, or the vinylene group in the polysiloxane segment.

All publicly known functional groups including the vinyl group, the vinylidene group, or the vinylene group can be used as the group having a polymerizable double bond. Among them, a (meth)acryloyl group represented by —R⁴—C(CH₃)═CH₂ or —R⁴—O—CO—C(CH₃)═CH₂ is preferred because such a (meth)acryloyl group has high reactivity during ultraviolet curing, has high compatibility with the vinyl-based polymer segment (a2) described below, and provides a cured film with high transparency.

The structural unit represented by the general formula (1) and/or the general formula (2) is a three-dimensional network polysiloxane structural unit in which two or three bonding arms of a silicon atom are involved in crosslinking. Although a three-dimensional network structure is formed, a dense network structure is not formed. Therefore, gelation or the like is not caused during the production or the formation of a primer, and storage stability is also improved.

(Composite Resin (A): Silanol Group and/or Hydrolyzable Silyl Group)

In the present invention, the silanol group is a silicon-containing group having a hydroxyl group directly bonded to a silicon atom. Specifically, the silanol group is preferably a silanol group obtained by bonding a hydrogen atom to an oxygen atom having a bonding arm in the structural unit represented by the general formula (1) and/or the general formula (2).

In the present invention, the hydrolyzable silyl group is a silicon-containing group having a hydrolyzable group directly bonded to a silicon atom. An example of the silyl group is a group represented by general formula (4).

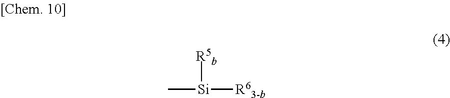

(In the general formula (4), R⁵ is a monovalent organic group such as an alkyl group, an aryl group, or an aralkyl group; R⁶ is a hydrolyzable group selected from the group consisting of a halogen atom, an alkoxy group, an acyloxy group, a phenoxy group, an aryloxy group, a mercapto group, an amino group, an amide group, an aminooxy group, an iminooxy group, and an alkenyloxy group; and b is an integer of 0 to 2.)

In the R⁵, examples of the alkyl group include a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a 1-methylbutyl group, a 2-methylbutyl group, a 1,2-dimethylpropyl group, a 1-ethylpropyl group, a hexyl group, an isohexyl group, a 1-methylpentyl group, a 2-methylpentyl group, a 3-methylpentyl group, a 1,1-dimethylbutyl group, a 1,2-dimethylbutyl group, a 2,2-dimethylbutyl group, a 1-ethylbutyl group, a 1,1,2-trimethylpropyl group, a 1,2,2-trimethylpropyl group, a 1-ethyl-2-methylpropyl group, and a 1-ethyl-1-methylpropyl group.

Examples of the aryl group include a phenyl group, a naphthyl group, a 2-methylphenyl group, a 3-methylphenyl group, a 4-methylphenyl group, a 4-vinylphenyl group, and a 3-isopropylphenyl group.

Examples of the aralkyl group include a benzyl group, a diphenylmethyl group, and a naphthylmethyl group.

In the R⁶, examples of the halogen atom include a fluorine atom, a chlorine atom, a bromine atom, and an iodine atom.

Examples of the alkoxy group include a methoxy group, an ethoxy group, a propoxy group, an isopropoxy group, a butoxy group, a sec-butoxy group, and a tert-butoxy group.

Examples of the acyloxy group include formyloxy, acetoxy, propanoyloxy, butanoyloxy, pivaloyloxy, pentanoyloxy, phenylacetoxy, acetoacetoxy, benzoyloxy, and naphthoyloxy.

Examples of the aryloxy group include phenyloxy and naphthyloxy.

Examples of the alkenyloxy group include a vinyloxy group, an allyloxy group, a 1-propenyloxy group, an isopropenyloxy group, a 2-butenyloxy group, a 3-butenyloxy group, a 2-pentenyloxy group, a 3-methyl-3-butenyloxy group, and a 2-hexenyloxy group.

When the hydrolyzable group represented by R⁶ is hydrolyzed, the hydrolyzable silyl group represented by the general formula (4) becomes a silanol group. A methoxy group or an ethoxy group is preferred because of its high hydrolyzability.

Specifically, the hydrolyzable silyl group is preferably a hydrolyzable silyl group obtained by bonding/substituting the above-described hydrolyzable group to/for an oxygen atom having a bonding arm in the structural unit represented by the general formula (1) and/or the general formula (2).

In the silanol group and the hydrolyzable silyl group, a hydrolysis condensation reaction proceeds between a hydroxyl group in the silanol group and the hydrolyzable group in the hydrolyzable silyl group. Therefore, the crosslinking density of a polysiloxane structure of a film obtained is increased, and thus a film having high solvent resistance and the like can be formed.

The polysiloxane segment (a1) having the silanol group and the hydrolyzable silyl group and the vinyl-based polymer segment (a2) described below are used when they are bonded to each other through the bond represented by the general formula (3).

As long as the polysiloxane segment (a1) has a structural unit represented by the general formula (1) and/or the general formula (2) and a silanol group and/or a hydrolyzable silyl group, the polysiloxane segment (a1) is not particularly limited and may have other groups.

For example, there may be employed a polysiloxane segment (a1) having, in a combined manner, a structural unit in which R¹ in the general formula (1) is an aryl group and a structural unit in which R¹ in the general formula (1) is an alkyl group such as methyl; a polysiloxane segment (a1) having, in a combined manner, a structural unit in which R¹ in the general formula (1) is a group having a polymerizable double bond, a structural unit in which R¹ in the general formula (1) is an aryl group, and a structural unit in which R² and R³ in the general formula (2) are each an alkyl group such as a methyl group; and a polysiloxane segment (a1) having, in a combined manner, a structural unit in which R¹ in the general formula (1) is a group having a polymerizable double bond and a structural in which one of R² and R³ in the general formula (2) is an aryl group.

Specifically, a structure in which at least one of R¹, R², and R³ is the aryl group in the polysiloxane segment (a1) is exemplified below.

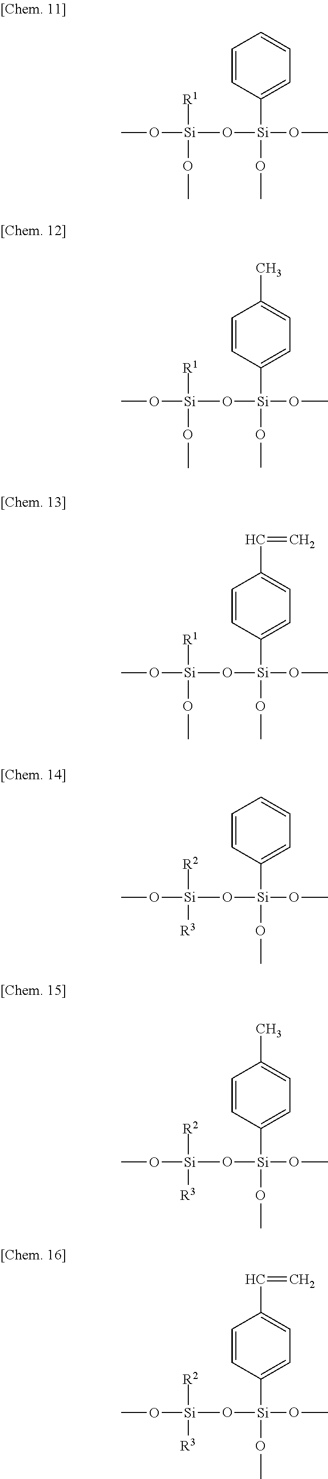

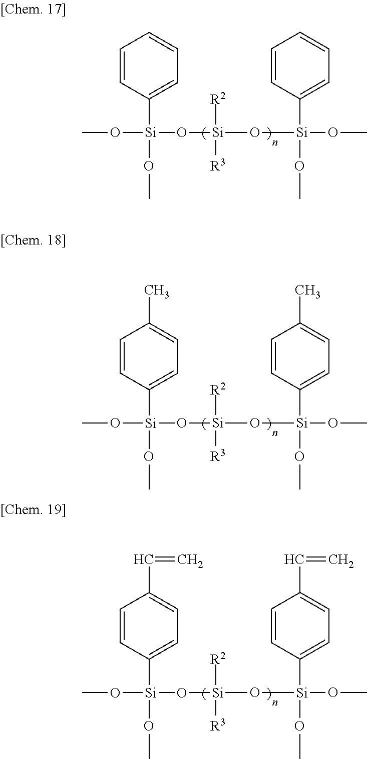

A structure in which at least one of R¹, R², and R³ is the group having a double bond in the polysiloxane segment (a1) is exemplified below.

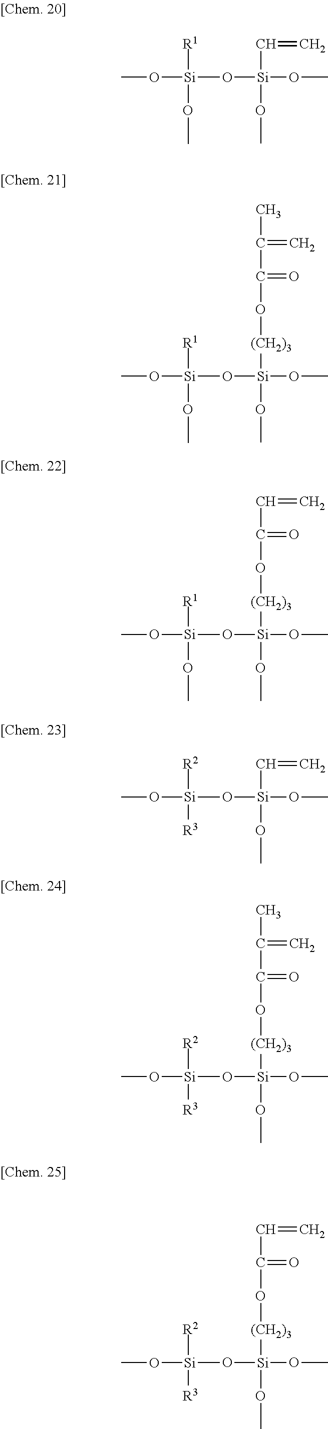

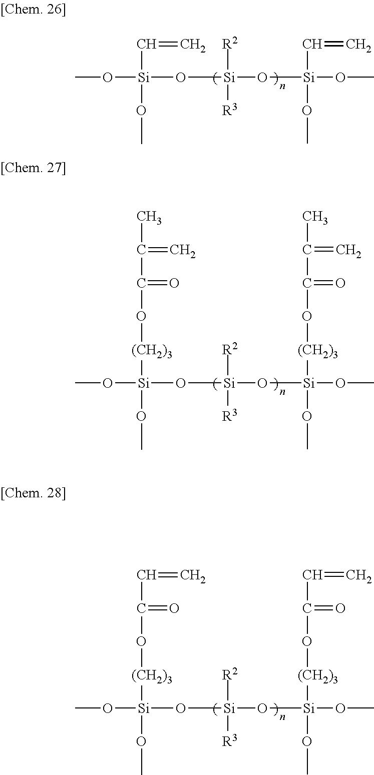

In the present invention, the content of the polysiloxane segment (a1) is preferably 10 to 65% by weight relative to the total solid content of the resin composition, which can achieve both scratch resistance and adhesion to a plastic substrate or the like.

(Composite Resin (A): Vinyl-Based Polymer Segment (a2))

The vinyl-based polymer segment (a2) according to the present invention is a vinyl polymer segment of an acrylic-based polymer, a fluoroolefin-based polymer, a vinyl ester-based polymer, an aromatic vinyl-based polymer, a polyolefin-based polymer, or the like. Preferably, these polymers are suitably selected in accordance with the applications. For example, an acrylic-based polymer segment is preferred to achieve the transparency and gloss of a surface layer obtained. An aromatic vinyl-based polymer segment is preferred to improve the hydrophilicity imparted through sulfonation.

The acrylic-based polymer segment is obtained by polymerizing or copolymerizing a typical (meth)acrylic monomer. Such a (meth)acrylic monomer is not particularly limited, and a vinyl monomer can also be copolymerized. Examples of the (meth)acrylic monomer include alkyl (meth)acrylates having an alkyl group with 1 to 22 carbon atoms, such as methyl (meth)acrylate, ethyl (meth)acrylate, n-propyl (meth)acrylate, n-butyl (meth)acrylate, isobutyl (meth)acrylate, tert-butyl (meth)acrylate, 2-ethylhexyl (meth)acrylate, and lauryl (meth)acrylate; aralkyl (meth)acrylates such as benzyl (meth)acrylate and 2-phenylethyl (meth)acrylate; cycloalkyl (meth)acrylates such as cyclohexyl (meth)acrylate and isobornyl (meth)acrylate; ω-alkoxyalkyl (meth)acrylates such as 2-methoxyethyl (meth)acrylate and 4-methoxybutyl (meth)acrylate; vinyl carboxylic acid esters such as vinyl acetate, vinyl propionate, vinyl pivalate, and vinyl benzoate; alkyl crotonic acid esters such as methyl crotonate and ethyl crotonate; dialkyl unsaturated dibasic acid esters such as dimethyl maleate, di-n-butyl maleate, dimethyl fumarate, and dimethyl itaconate; α-olefins such as ethylene and propylene; fluoroolefins such as vinylidene fluoride, tetrafluoroethylene, hexafluoropropylene, and chlorotrifluoroethylene; alkyl vinyl ethers such as ethyl vinyl ether and n-butyl vinyl ether; cycloalkyl vinyl ethers such as cyclopentyl vinyl ether and cyclohexyl vinyl ether; and monomers having a tertiary amide group such as N,N-dimethyl (meth) acrylamide, N-(meth)acryloylmorpholine, N-(meth)acryloylpyrrolidine, and N-vinylpyrrolidone.

The aromatic vinyl-based polymer segment is obtained by polymerizing or copolymerizing an aromatic vinyl-based monomer such as styrene, p-tert-butylstyrene, α-methylstyrene, or vinyltoluene. In the case of copolymerization, the above-described (meth)acrylic monomer is preferably copolymerized.

A polymerization method, a solvent, or a polymerization initiator used when the monomers are copolymerized is not particularly limited, and the vinyl-based polymer segment (a2) can be obtained by a publicly known method. For example, the vinyl-based polymer segment (a2) can be obtained by various polymerization methods such as bulk radical polymerization, solution radical polymerization, and nonaqueous dispersion radical polymerization using a polymerization initiator such as 2,2′-azobis(isobutyronitrile), 2,2′-azobis(2,4-dimethylvaleronitrile), 2,2′-azobis(2-methylbutyronitrile), tert-butyl peroxypivalate, tert-butyl peroxybenzoate, tert-butyl peroxy-2-ethylhexanoate, di-tert-butyl peroxide, cumene hydroperoxide, or diisopropyl peroxycarbonate.

The number-average molecular weight (hereinafter abbreviated as Mn) of the vinyl-based polymer segment (a2) is preferably 500 to 200,000, which can prevent an increase in viscosity and gelation caused when the composite resin (A) is produced and provide high durability. Mn is more preferably 700 to 100,000 and further preferably 1,000 to 50,000 because, for example, a satisfactory film can be formed on a substrate.

In order to obtain the composite resin (A) obtained by bonding the polysiloxane segment (a1) and the vinyl-based polymer segment (a2) to each other through the bond represented by the general formula (3), the vinyl-based polymer segment (a2) has a silanol group and/or a hydrolyzable silyl group directly bonded to a carbon bond in the vinyl-based polymer segment (a2). The silanol group and/or the hydrolyzable silyl group are scarcely present in the vinyl-based polymer segment (a2) of the composite resin (A), which is an end product, because the bond represented by the general formula (3) is formed when the composite resin (A) described below is produced. However, there is no problem even if the silanol group and/or the hydrolyzable silyl group are left in the vinyl-based polymer segment (a2). A film is formed through a curing reaction of the group having a polymerizable double bond while at the same time a hydrolysis condensation reaction proceeds between a hydroxyl group in the silanol group and the hydrolyzable group in the hydrolyzable silyl group. Therefore, the crosslinking density of a polysiloxane structure of a film obtained is increased and thus a film having high solvent resistance and the like can be formed.

Specifically, a vinyl-based polymer segment (a2) having a silanol group and/or a hydrolyzable silyl group directly bonded to a carbon bond is obtained by copolymerizing the above-described typical monomer and a vinyl-based monomer having a silanol group and/or a hydrolyzable silyl group directly bonded to a carbon bond.

Examples of the vinyl-based monomer having a silanol group and/or a hydrolyzable silyl group directly bonded to a carbon bond include vinyltrimethoxysilane, vinyltriethoxysilane, vinylmethyldimethoxysilane, vinyltri(2-methoxyethoxy)silane, vinyltriacetoxysilane, vinyltrichlorosilane, 2-trimethoxysilylethyl vinyl ether, 3-(meth) acryloyloxypropyltrimethoxysilane, 3-(meth) acryloyloxypropyltriethoxysilane, 3-(meth) acryloyloxypropylmethyldimethoxysilane, and 3-(meth) acryloyloxypropyltrichlorosilane. Among them, vinyltrimethoxysilane and 3-(meth) acryloyloxypropyltrimethoxysilane are preferred because a hydrolysis reaction can be easily caused to proceed and by-products after the reaction can be easily removed.

In the case where a crosslinking agent such as polyisocyanate described below is contained, the vinyl-based polymer segment (a2) preferably has a reactive functional group such as an alcoholic hydroxyl group. For example, a vinyl-based polymer segment (a2) having an alcoholic hydroxyl group can be obtained by copolymerizing a (meth)acrylic monomer having an alcoholic hydroxyl group. Examples of the (meth)acrylic monomer having an alcoholic hydroxyl group include 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, 3-chloro-2-hydroxypropyl (meth)acrylate, di-2-hydroxyethyl fumarate, mono-2-hydroxyethylmonobutyl fumarate, polyethylene glycol mono(meth)acrylate, polypropylene glycol mono(meth)acrylate, various hydroxyalkyl esters of α,β-ethylenic unsaturated carboxylic acids such as “PLACCEL FM or PLACCEL FA” [caprolactone-addition monomer available from DAICEL CHEMICAL INDUSTRIES, LTD.], and addition products between ε-caprolactone and the foregoing.

Among them, 2-hydroxyethyl (meth)acrylate is preferred because the reaction is easily caused.

Preferably, the amount of the alcoholic hydroxyl group is suitably calculated and determined from the amount of the below-described polyisocyanate added.

### (Method for Producing Composite Resin (A))

The composite resin (A) used in the present invention is specifically produced by (method 1), (method 2), or (method 3) below.

### (Method 1)

The above-described typical (meth)acrylic monomer and the vinyl-based monomer having a silanol group and/or a hydrolyzable silyl group directly bonded to a carbon bond are copolymerized to obtain a vinyl-based polymer segment (a2) having a silanol group and/or a hydrolyzable silyl group directly bonded to a carbon bond. The vinyl-based polymer segment (a2) is mixed with a silane compound to cause a hydrolysis condensation reaction. If there is a group desired to be introduced, a silane compound having the desired group is used. For example, when an aryl group is introduced, a silane compound having an aryl group and a silanol group and/or a hydrolyzable silyl group may be suitably used. When a group having a polymerizable double bond is introduced, a silane compound having a group with a polymerizable double bond and a silanol group and/or a hydrolyzable silyl group may be suitably used.

In this method, a hydrolysis condensation reaction is caused between a silanol group or a hydrolyzable silyl group of the silane compound and a silanol group and/or a hydrolyzable silyl group of the vinyl-based polymer segment (a2) having a silanol group and/or a hydrolyzable silyl group directly bonded to a carbon bond. As a result, the polysiloxane segment (a1) is formed while at the same time the composite resin (A) is obtained by bonding the polysiloxane segment (a1) and the vinyl-based polymer segment (a2) to each other through the bond represented by the general formula (3).

### (Method 2)

In the same manner as in the method 1, there is obtained the vinyl-based polymer segment (a2) having a silanol group and/or a hydrolyzable silyl group directly bonded to a carbon bond.

A hydrolysis condensation reaction is caused on a silane compound (if there is a group desired to be introduced, a silane compound having the desired group is used) to obtain the polysiloxane segment (a1). Subsequently, a hydrolysis condensation reaction is caused between a silanol group and/or a hydrolyzable silyl group of the vinyl-based polymer segment (a2) and a silanol group and/or a hydrolyzable silyl group of the polysiloxane segment (a1).

### (Method 3)

In the same manner as in the method 1, there is obtained the vinyl-based polymer segment (a2) having a silanol group and/or a hydrolyzable silyl group directly bonded to a carbon bond. In the same manner as in the method 2, the polysiloxane segment (a1) is obtained. Furthermore, a silane compound having a group desired to be introduced is optionally added to cause a hydrolysis condensation reaction.

In the (method 1) to (method 3), examples of the silane compound having an aryl group used when an aryl group is introduced and a silanol group and/or a hydrolyzable silyl group include various organotrialkoxysilanes such as phenyltrimethoxysilane and phenyltriethoxysilane; various diorganodialkoxysilanes such as diphenyldimethoxysilane and methylphenyldimethoxysilane; and chlorosilanes such as phenyltrichlorosilane and diphenyldichlorosilane. Among them, organotrialkoxysilanes and diorganodialkoxysilanes can be used because a hydrolysis reaction can be easily caused to proceed and by-products after the reaction can be easily removed.

Examples of the silane compound having both of a group with a polymerizable double bond used when a group with a polymerizable double bond is introduced and a silanol group and/or a hydrolyzable silyl group include vinyltrimethoxysilane, vinyltriethoxysilane, vinylmethyldimethoxysilane, vinyltri(2-methoxyethoxy)silane, vinyltriacetoxysilane, vinyltrichlorosilane, 2-trimethoxysilylethyl vinyl ether, 3-(meth) acryloyloxypropyltrimethoxysilane, 3-(meth) acryloyloxypropyltriethoxysilane, 3-(meth) acryloyloxypropylmethyldimethoxysilane, and 3-(meth) acryloyloxypropyltrichlorosilane. Among them, vinyltrimethoxysilane and 3-(meth) acryloyloxypropyltrimethoxysilane are preferred because a hydrolysis reaction can be easily caused to proceed and by-products after the reaction can be easily removed.

In addition, examples of a typical silane compound used in the (method 1) to (method 3) include various organotrialkoxysilanes such as methyltrimethoxysilane, methyltriethoxysilane, methyltri-n-butoxysilane, ethyltrimethoxysilane, n-propyltrimethoxysilane, isobutyltrimethoxysilane, and cyclohexyltrimethoxysilane; various diorganodialkoxysilanes such as dimethyldimethoxysilane, dimethyldiethoxysilane, dimethyldi-n-butoxysilane, diethyldimethoxysilane, and methylcyclohexyldimethoxysilane; and chlorosilanes such as methyltrichlorosilane, ethyltrichlorosilane, vinyltrichlorosilane, dimethyldichlorosilane, and diethyldichlorosilane. Among them, organotrialkoxysilanes and diorganodialkoxysilanes are preferred because a hydrolysis reaction can be easily caused to proceed and by-products after the reaction can be easily removed.

A tetrafunctional alkoxy silane compound such as tetramethoxysilane, tetraethoxysilane, or tetra-n-propoxysilane or a partial hydrolysis condensate of the tetrafunctional alkoxy silane compound can be used in combination as long as the advantages of the present invention are not impaired. When the tetrafunctional alkoxy silane compound or the partial hydrolysis condensate thereof is used in combination, the ratio of silicon atoms contained in the tetrafunctional alkoxy silane compound relative to all the silicon atoms that constitute the polysiloxane segment (a1) is preferably 20 mol % or less.

A metal alkoxide compound with a metal other than silicon, such as boron, titanium, zirconium, or aluminum, can be used in combination with the silane compound as long as the advantages of the present invention are not impaired. For example, the ratio of metal atoms contained in the metal alkoxide compound relative to all the silicon atoms that constitute the polysiloxane segment (a1) is preferably 25 mol % or less.

In the hydrolysis condensation reaction in the (method 1) to (method 3), part of the hydrolyzable group is hydrolyzed due to the effect of water or the like to form a hydroxyl group and then a condensation reaction proceeds between the hydroxyl groups or between the hydroxyl group and a hydrolyzable group. The hydrolysis condensation reaction can be caused to proceed by a publicly known method, but a method for causing the reaction to proceed by supplying water and a catalyst in the above-described production step is preferred because of its convenience.

Examples of the catalyst used include inorganic acids such as hydrochloric acid, sulfuric acid, and phosphoric acid; organic acids such as p-toluenesulfonic acid, monoisopropyl phosphate, and acetic acid; inorganic bases such as sodium hydroxide and potassium hydroxide; titanic acid esters such as tetraisopropyl titanate and tetrabutyl titanate; various compounds containing basic nitrogen atoms such as 1,8-diazabicyclo[5.4.0]undecene-7 (DBU), 1,5-diazabicyclo[4.3.0]nonene-5 (DBN), 1,4-diazabicyclo[2.2.2]octane (DABCO), tri-n-butylamine, dimethylbenzylamine, monoethanolamine, imidazole, and 1-methylimidazole; various quaternary ammonium salts having chloride, bromide, carboxylate, hydroxide, or the like as a counteranion, such as tetramethylammonium salts, tetrabutylammonium salts, and dilauryldimethylammonium salts; tin carboxylates such as dibutyltin diacetate, dibutyltin dioctoate, dibutyltin dilaurate, dibutyltin diacetylacetonate, tin octylate, and tin stearate. These catalysts may be used alone or in combination of two or more.

The amount of the catalyst added is not particularly limited, but is preferably 0.0001 to 10% by weight, more preferably 0.0005 to 3% by weight, and particularly preferably 0.001 to 1% by weight relative to the total amount of the compounds each having a silanol group or a hydrolyzable silyl group.

The amount of water supplied is preferably 0.05 mol or more, more preferably 0.1 mol or more, and particularly preferably 0.5 mol or more relative to 1 mol of a silanol group or a hydrolyzable silyl group of the compounds each having a silanol group or a hydrolyzable silyl group.

The catalyst and water may be collectively or consecutively supplied or a mixture of the catalyst and water may be supplied.

The reaction temperature of the hydrolysis condensation reaction in the (method 1) to (method 3) is suitably 0 to 150° C. and preferably 20 to 100° C. The reaction can be caused under normal pressure, increased pressure, or reduced pressure. An alcohol and water, which are by-products of the hydrolysis condensation reaction, may be optionally removed by a method such as distillation.

The ratio of compounds prepared in the (method 1) to (method 3) is suitably selected in accordance with the desired structure of the composite resin (A) used in the present invention. To achieve high durability for a film obtained, the composite resin (A) is obtained so that the content of the polysiloxane segment (a1) is preferably 30 to 95% by weight and more preferably 30 to 75% by weight.

In the (method 1) to (method 3), the polysiloxane segment and the vinyl-based polymer segment are combined with each other in a block manner by the following method. A vinyl-based polymer segment having a structure in which the silanol group and/or the hydrolyzable silyl group is present at only one terminal or both terminals of a polymer chain is used as an intermediate. For example, in the case of the (method 1), a silane compound is added to the vinyl-based polymer segment to cause a hydrolysis condensation reaction.

In the (method 1) to (method 3), the polysiloxane segment is combined with the vinyl-based polymer segment in a graft manner by the following method. A vinyl-based polymer segment having a structure in which the silanol group and/or the hydrolyzable silyl group is randomly distributed to the main chain of the vinyl-based polymer segment is used as an intermediate. For example, in the case of the (method 2), a hydrolysis condensation reaction is caused between a silane compound and the silanol group and/or the hydrolyzable silyl group of the vinyl-based polymer segment.

### (Resin Composition: Other Resins Having an Aryl Group)

The composite resin (A) and an acrylic-based or styrene-based resin having an aryl group are preferably used in combination because the hydrophilicity of a surface-treated substrate can be further improved. An example of such a resin is an aromatic vinyl-based polymer or the like used as the vinyl-based polymer segment (a2) in the composite resin (A). The number-average molecular weight of the aromatic vinyl-based polymer is preferably 1000 to 10000 because a satisfactory film can be formed on a substrate. The number of aryl groups depends on the desired degree of hydrophilicity, but is preferably 5.0 to 60 mol %.

### (Resin Composition: Polyisocyanate (B))

By introducing a reactive functional group into the composite resin (A) and using a crosslinking agent or the like, a layer having a high degree of crosslinking and high weather resistance and scratch resistance is obtained. Polyisocyanate (B) is preferred as the crosslinking agent. In this case, the vinyl-based polymer segment (a2) in the composite resin (A) preferably has an alcoholic hydroxyl group. Herein, the content of the polyisocyanate (B) is preferably 5 to 50% by weight relative to the total solid content of the active energy ray-curable resin layer. By incorporating the polyisocyanate (B) within the range, there is obtained a film having high long-term weather resistance (specifically crack resistance) in the open air. This may be because polyisocyanate and a hydroxyl group in the system (a hydroxyl group in the vinyl-based polymer segment (a2) or a hydroxyl group in the below-described active energy ray-curable monomer having an alcoholic hydroxyl group) react with each other and consequently a urethane bond, which is a soft segment, is formed, and thus the urethane bond reduces the concentration of stress caused by curing derived from polymerizable double bonds.

The polyisocyanate (B) used is not particularly limited, and publicly known polyisocyanate can be used. However, polyisocyanate mainly composed of an aromatic diisocyanate such as tolylenediisocyanate or diphenylmethane-4,4′-diisocyanate or an aralkyl diisocyanate such as m-xylylene diisocyanate and α,α,α′,α′-tetramethyl-m-xylylene diisocyanate is preferably used in the minimum amount because the cured film turns yellow after long-term outdoor exposure.

In view of long-term use in the open air, an aliphatic polyisocyanate mainly composed of an aliphatic diisocyanate is suitable as the polyisocyanate used in the present invention. Examples of the aliphatic diisocyanate include tetramethylene diisocyanate, 1,5-pentamethylene diisocyanate, 1,6-hexamethylene diisocyanate (hereinafter abbreviated as “HDI”), 2,2,4- or 2,4,4-trimethyl-1,6-hexamethylene diisocyanate, lysine isocyanate, isophorone diisocyanate, hydrogenated xylene diisocyanate, hydrogenated diphenylmethane diisocyanate, 1,4-diisocyanatocyclohexane, 1,3-bis(diisocyanatomethyl)cyclohexane, and 4,4′-dicyclohexylmethane diisocyanate. Among them, HDI is particularly suitable in terms of crack resistance and cost.

Examples of an aliphatic polyisocyanate obtained from the aliphatic diisocyanate include allophanate-type polyisocyanate, biuret-type polyisocyanate, adduct-type polyisocyanate, and isocyanurate-type polyisocyanate, all of which can be suitably used.

A so-called block polyisocyanate compound obtained so as to have a block structure using various blocking agents can also be used as the above-described polyisocyanate. Examples of the blocking agents include alcohols such as methanol, ethanol, and lactic acid ester; phenolic compounds having a hydroxyl group such as phenol and salicylic acid ester; amides such as ε-caprolactam and 2-pyrrolidone; oximes such as acetone oxime and methyl ethyl ketone oxime; and active methylene compounds such as methyl acetoacetate, ethyl acetoacetate, and acetylacetone.

The ratio of the isocyanate group in the polyisocyanate (B) is preferably 3 to 30% by weight in terms of the crack resistance and wear resistance of a cured film obtained. If the ratio of the isocyanate group in the polyisocyanate (B) is more than 30%, the molecular weight of polyisocyanate is decreased. Consequently, crack resistance as a result of stress relaxation is sometimes not achieved.

Polyisocyanate and a hydroxyl group in the system (a hydroxyl group in the vinyl-based polymer segment (a2) or a hydroxyl group in the below-described active energy ray-curable monomer having an alcoholic hydroxyl group) gradually react with each other at room temperature without applying heat. If necessary, heating at 80° C. may be performed for several minutes to several hours (20 minutes to 4 hours) to facilitate the reaction between the alcoholic hydroxyl group and the isocyanate. In this case, a publicly known urethane-forming catalyst may be optionally used. The urethane-forming catalyst is suitably selected in accordance with the desired reaction temperature.

### (Resin Composition: Other Additives)

In the case where the composite resin (A) has the group with a polymerizable double bond, the resin composition used in the present invention can be cured with active energy rays. Examples of the active energy rays include ultraviolet rays emitted from a light source such as a xenon lamp, a low-pressure mercury lamp, a high-pressure mercury lamp, an ultrahigh-pressure mercury lamp, a metal halide lamp, a carbon arc lamp, or a tungsten lamp; electron beams normally taken from a particle accelerator with 20 to 2000 kV; and α rays, β rays, and γ rays. Among them, ultraviolet rays or electron beams are preferably used. In particular, ultraviolet rays are suitable. Examples of an ultraviolet-ray source include sunrays, a low-pressure mercury lamp, a high-pressure mercury lamp, an ultrahigh-pressure mercury lamp, a carbon arc lamp, a metal halide lamp, a xenon lamp, an argon laser, and a helium-cadmium laser. Using such an ultraviolet-ray source, a coating surface of the active energy ray-curable resin layer is irradiated with ultraviolet rays having a wavelength of about 180 to 400 nm, whereby a film can be cured. The ultraviolet radiation dose is suitably selected in accordance with the type and quantity of a photopolymerization initiator used.

The curing performed with active energy rays is particularly effective when a substrate is composed of a material having poor heat resistance, such as a plastic. In the case where heat is used together to the extent that a substrate is not affected, a publicly known heat source such as hot air or near infrared rays can be used.

When curing is performed with ultraviolet rays, a photopolymerization initiator is preferably used. A publicly known photopolymerization initiator may be used, and at least one selected from the group consisting of acetophenones, benzylketals, and benzophenones is preferably used. Examples of the acetophenones include diethoxyacetophenone, 2-hydroxy-2-methyl-1-phenylpropan-1-on, 1-(4-isopropylphenyl)-2-hydroxy-2-methylpropan-1-on, and 4-(2-hydroxyethoxy)phenyl-(2-hydroxy-2-propyl)ketone. Examples of the benzylketals include 1-hydroxycyclohexyl phenyl ketone and benzyldimethylketal. Examples of the benzophenones include benzophenone and methyl o-benzoylbenzoate. Examples of the benzoins include benzoin, benzoin methyl ether, and benzoin isopropyl ether. The photopolymerization initiators (B) may be used alone or in combination of two or more.

The amount of the photopolymerization initiator (B) used is preferably 1 to 15% by weight and more preferably 2 to 10% by weight relative to 100% by weight of the composite resin (A).

If necessary, an active energy ray-curable monomer, particularly a multifunctional (meth)acrylate, is preferably contained. The multifunctional (meth)acrylate is not particularly limited, and a publicly known multifunctional (meth)acrylate can be used. Examples of the multifunctional (meth)acrylate include multifunctional (meth)acrylates having two or more polymerizable double bonds in a single molecule, such as 1,2-ethanediol diacrylate, 1,2-propanediol diacrylate, 1,4-butanediol diacrylate, 1,6-hexanediol diacrylate, dipropylene glycol diacrylate, neopentyl glycol diacrylate, tripropylene glycol diacrylate, trimethylolpropane diacrylate, trimethylolpropane triacrylate, tris(2-acryloyloxy) isocyanurate, pentaerythritol triacrylate, pentaerythritol tetraacrylate, di(trimethylolpropane) tetraacrylate, di(pentaerythritol) pentaacrylate, and di(pentaerythritol) hexaacrylate. In addition, a urethane acrylate, a polyester acrylate, an epoxy acrylate, and the like can be exemplified as the multifunctional acrylate. They may be used alone or in combination of two or more.

For example, in the case where the above-described polyisocyanate is used together, an acrylate having a hydroxyl group, such as pentaerythritol triacrylate or dipentaerythritol pentaacrylate, is preferred. To further increase the crosslinking density, it is effective to use a (meth)acrylate having a larger number of functional groups, such as di(pentaerythritol) pentaacrylate or di(pentaerythritol) hexaacrylate.

A monofunctional (meth)acrylate can also be used together with the multifunctional (meth)acrylate. Examples of the monofunctional (meth)acrylate include (meth)acrylic acid esters having a hydroxyl group, such as hydroxyethyl (meth)acrylate, hydroxypropyl (meth)acrylate, hydroxybutyl (meth)acrylate, caprolactone-modified hydroxy (meth)acrylate (e.g., product name “PLACCEL” available from DAICEL CHEMICAL INDUSTRIES, LTD.), mono(meth)acrylate of polyester diol obtained from phthalic acid and propylene glycol, mono(meth)acrylate of polyester diol obtained from succinic acid and propylene glycol, polyethylene glycol mono(meth)acrylate, polypropylene glycol mono(meth)acrylate, pentaerythritol tri(meth)acrylate, 2-hydroxy-3-(meth) acryloyloxypropyl (meth)acrylate, and various (meth)acrylic acid adducts of epoxy esters; vinyl monomers having a carboxyl group, such as (meth)acrylic acid, crotonic acid, itaconic acid, maleic acid, and fumaric acid; vinyl monomers having a sulfonic acid group, such as vinylsulfonic acid, styrenesulfonic acid, and sulfoethyl (meth)acrylate; acid phosphate-based vinyl monomers such as 2-(meth)acryloyloxyethyl acid phosphate, 2-(meth) acryloyloxypropyl acid phosphate, 2-(meth)acryloyloxy-3-chloropropyl acid phosphate, and 2-methacryloyloxyethylphenylphosphoric acid; and vinyl monomers having a methylol group such as N-methylol (meth)acrylamide. They can be used alone or in combination of two or more. In consideration of the reactivity with an isocyanate group of the multifunctional isocyanate (b), a (meth)acrylic acid ester having a hydroxyl group is particularly preferred as a monomer (c).

The amount of the multifunctional acrylate used is preferably 1 to 85% by weight and more preferably 5 to 80% by weight relative to the total solid content of the resin composition used as the active energy ray-curable resin layer. By using the multifunctional acrylate within the range, the physical properties such as hardness of a layer obtained can be improved.

In the case where heat curing is used together, each catalyst is preferably selected in consideration of the reaction of polymerizable double bonds in the composition and the reaction temperature and time of a urethane-forming reaction between an alcoholic hydroxyl group and isocyanate. A thermosetting resin can also be used together. Examples of the thermosetting resin include vinyl-based resin, unsaturated polyester resin, polyurethane resin, epoxy resin, epoxy ester resin, acrylic resin, phenol resin, petroleum resin, ketone resin, silicon resin, and modified resin of the foregoing.

In addition, various additives such as an organic solvent, an inorganic solvent, an organic pigment, an extender, a clay mineral, a wax, a surfactant, a stabilizer, a fluidity adjusting agent, a dye, a leveling agent, a rheology controlling agent, an ultraviolet absorber, an antioxidant, and a plasticizer can be optionally used.

### (Substrate)

A substrate to which the present invention is applicable is not particularly limited. The substrate may be composed of any material as long as the resin composition can be applied to the material. Examples of the material of the substrate include metal, plastic, glass, ceramic, paper, nonwoven fabric, other inorganic and organic materials, and the combination of the foregoing (e.g., composite materials and laminated materials). To ease the coating, for example, a primer layer may be disposed or corona treatment may be performed.

The shape of the substrate is also not particularly limited. The substrate may have any shape adequate for the purpose, such as a plate-like shape or a three-dimensional shape having a curvature over the entirety or part thereof. The hardness, thickness, and the like of the substrate are also not particularly limited.

A surface-treated substrate can be directly used as various items and components. Such components may be a molded article having three-dimensional shape or a sheet such as a sheet for molding or a decorative sheet used through attachment or thermocompression bonding to the surface of a molded article. The present invention can be applied to such components.

If the substrate is, for example, a molded article having a three-dimensional shape (e.g., a body of an automobile), a surface-treated molded article can be obtained by forming a cured material layer composed of the resin composition on the surface of the molded article by coating and then by bringing a sulfur trioxide-containing gas into contact with the cured material layer. The surface-treated molded article can be directly used as a single component of an automobile.

Specific examples of the molded article include items and components having a three-dimensional shape, e.g., transport machines such as an automobile, a motorcycle, an electric train, a bicycle, a ship, and an airplane and various components used for the foregoing; household electric appliances such as a television, a radio, a refrigerator, a washing machine, an air conditioner, an outdoor unit of an air conditioner, and a computer and various components used for the foregoing; construction materials such as a window pane, an inorganic tile, a metallic roofing material, an inorganic exterior wall material, a metallic wall material, a metallic window frame, and a metallic or wooden door or interior wall material; bathroom components such as a waterproof pan of a prefabricated bath, a wall, a ceiling, and a washstand; kitchen components such as a kitchen sink, a kitchen counter, and the top of a cooking stove; outdoor structures such as a road, a traffic sign, a guardrail, a bridge, a tank, a chimney, and a building; containers such as a plastic bottle and a metal can; and musical instruments, office supplies, sporting goods, and toys composed of the above-described substrate.

If the substrate is a flexible sheet such as a nonwoven fabric sheet or a plastic film, a surface-treated sheet can be obtained by forming a cured material layer composed of the resin composition on the surface of the sheet or film or the surface of a molded article and then by bringing a sulfur trioxide-containing gas into contact with the cured material layer. Such a sheet is used as an adhesive film by providing an adhesive or the like on the surface opposite the surface treated. The adhesive film is used as a clear film for windows of automobiles or a decorative sheet. Furthermore, such a sheet is used as a sheet for decorative molding by providing a printing layer. The sheet for decorative molding can be used for insert decorative molding or decorative molding for FRP/SMC. In addition, such a sheet can be directly used as an item or a single component.

Specifically, there are exemplified various films for construction materials such as a clear film for windows, a decorative film, and a poster that use a polyester resin film, an acrylic resin film, or a fluorocarbon resin film as a substrate; components that constitute a solar cell module; and components that constitute a flat panel display, such as a polarizing plate-protecting film, an AR film, a polarizing plate, a phase difference film, a prism sheet, a diffusing film, and a diffusing plate.

In particular when the surface-treated sheet is used as a component that constitutes a solar cell module, the surface-treated sheet is preferably used as a protective component because the advantages of the present invention can be achieved. When the surface-treated sheet is used as a light-receiving-side transparent protective component, the substrate is preferably composed of a transparent plastic or glass in terms of transparency. When the surface-treated sheet is used as a back side protective component, the substrate is not particularly limited and can be composed of a typical glass or plastic (not necessarily having transparency).

### (Method for Surface-Treating Substrate: Step (1))

In the case where the substrate is an item or component having a three-dimensional shape, the resin composition layer is preferably formed on the substrate by a publicly known coating method such as a brushing method, a roller coating method, a spray coating method, a dip coating method, a flow coater method, a roll coater method, or an electrodeposition method.

In the case where the substrate is a flexible sheet and is applied to a decorative sheet or a sheet for molding, the resin composition layer is formed on a sheet-shaped plastic substrate by a flow coater method, a roll coater method, a spraying method, an airless spraying method, an air spraying method, a brushing method, a roller coating method, a troweling method, a dipping method, a pulling method, a nozzle method, a winding method, a flowing method, a piling method, or a patching method. In the case where a decorative layer such as a printing layer or a primer layer is further formed, there is exemplified a transfer method in which a substrate having the resin composition layer formed thereon and a certain detachable film having the decorative layer or primer layer formed thereon are bonded to each other by dry lamination so that the resin composition layer faces the decorative layer or primer layer. Among them, a transfer method is preferred.

Examples of a material of the sheet-shaped plastic substrate include polyolefins such as polyethylene, polypropylene, and ethylene-propylene copolymer; polyesters such as polyethylene isophthalate, polyethylene terephthalate, polyethylene naphthalate, and polybutylene terephthalate; polyamides such as nylon 1, nylon 11, nylon 6, nylon 66, and nylon MX-D; styrene-based polymers such as polystyrene, styrene-butadiene block copolymer, styrene-acrylonitrile copolymer, and styrene-butadiene-acrylonitrile copolymer (ABS resin); acrylic-based polymers such as polymethyl methacrylate and methyl methacrylate-ethyl methacrylate copolymer; and polycarbonate. The plastic substrate may have a layered structure with a single layer or two or more layers. The plastic substrate may be non-stretched, uniaxially stretched, or biaxially stretched. Publicly known additives such as an antistatic agent, an antifogging agent, an antiblocking agent, an ultraviolet absorber, an antioxidant, a light stabilizer, a nucleating agent, and a lubricant may be optionally added as long as the advantages of the present invention are not impaired. To further improve the adhesiveness with the curable resin composition of the present invention, publicly known surface treatment may be performed on the surface of the plastic substrate. Examples of the surface treatment include corona discharge treatment, plasma treatment, frame plasma treatment, electron irradiation treatment, and ultraviolet irradiation treatment. These treatments may be used alone or in combination of two or more. To improve the adhesiveness with the resin composition layer, an undercoat is sometimes applied.

Examples of a paper substrate that can be used include titanium paper for construction materials, tissue paper for construction materials, printing paper, pure white paper, bleached or unbleached kraft paper, so-called mixed paper made by mixing synthetic resins, impregnated titanium paper made by impregnating titanium paper with a resin such as latex, and coated impregnated titanium paper made by coating titanium paper with latex or the like.

A pattern or the like can be printed on the paper substrate by a publicly known printing method. Furthermore, a publicly known recoating agent mainly composed of polyester resin or cellulose resin can also be applied on the printed surface.

The thickness of the plastic substrate depends on the applications, but the plastic substrate can be suitably used when it has a thickness of 30 to 200 μm. The paper substrate has a basis weight of 30 to 120 g/m² and preferably 60 to 80 g/m². Under this condition, impregnated titanium paper having high paper strength and few air bubbles therein is preferred.

A cured material layer is obtained by curing the resin composition layer by a certain method. Since the composite resin (A) has a silanol group and/or a hydrolyzable silyl group, the reaction gradually proceeds even at room temperature and thus a cured material layer is formed. However, to further accelerate the reaction, heating is preferably performed. In the case where the composite resin (A) has a group with a polymerizable double bond, the resin composition layer is preferably cured with active energy rays. In the case where the polyisocyanate (B) is contained, the curing is preferably performed by heating.

The thickness of the resin composition layer is preferably 0.1 to 300 μm because a cured film having high scratch resistance can be formed.

### (Method for Surface-Treating Substrate: Step (2))

A sulfur trioxide-containing gas is, by a publicly known method, brought into contact with the cured material layer composed of the resin composition and formed on the substrate in the step (1).

The sulfur trioxide gas is not particularly limited. The sulfur trioxide gas can be supplied through gasification of liquid stabilized sulfur trioxide (boiling point 44.8° C.), vaporization of fuming sulfuric acid, or catalytic oxidation of sulfur dioxide gas generated by subjecting sulfur to air combustion.

A dry gas that does not react with sulfur trioxide is typically used as a dry gas for dilution. Examples of the dry gas include dry nitrogen, inert gases such as helium and argon, and dry air. In view of cost, dry air is preferably used. The sulfur trioxide-containing gas is preferably heated. The temperature is preferably 40 to 120° C. and more preferably 40 to 100° C.

The concentration of the sulfur trioxide gas is preferably 0.1 to 10% by volume and more preferably 0.1 to 5% by volume. If the concentration is less than 0.1% by volume, the surface is sometimes not sufficiently reformed. If the concentration is more than 10% by volume, the cured material layer composed of the resin composition tends to be easily degraded.

The ambient temperature in the container at the time when the sulfur trioxide-containing gas is brought into contact with the substrate including the cured material layer composed of the resin composition depends on the material of the substrate to be reformed, but is preferably 20 to 120° C. and more preferably 30 to 100° C. If the ambient temperature is less than 20° C., the surface is sometimes not sufficiently reformed. If the ambient temperature is more than 120° C., the resin composition layer tends to be easily degraded.

The contact time when the sulfur trioxide-containing gas is in contact with the substrate including the cured material layer composed of the resin composition depends on the material of the substrate to be reformed, but is preferably 1 to 120 minutes, more preferably 1 to 30 minutes in terms of productivity, and further preferably 5 to 20 minutes. If the contact time is less than 1 minute, the surface is sometimes not sufficiently reformed and the product quality may significantly vary. If the contact time is more than 120 minutes, the cured material layer composed of the resin composition tends to be easily degraded.

A method for supplying the sulfur trioxide-containing gas is not particularly limited. For example, a sulfur trioxide-containing gas is caused to continuously flow in a single direction and the gas may be sent to exhaust gas treatment equipment. Alternatively, the gas may undergo external circulation using an air supply fan or the like. Herein, the gas flow rate depends on the internal volume of the container and is preferably 0.5 to 10 times and more preferably 1 to 5 times the volume of the container per minute. Furthermore, after the pressure is reduced in the step 2, the pressure is returned to normal pressure in a form of mixed gas and then the state may be maintained without causing the gas to flow while the container is sealed. For example, in the case of the flowing system that uses a container having an internal volume of 2 liters (L), the gas flow rate is 1 L/min to 20 L/min.

In terms of quality, the amount of water in the reaction vessel is preferably controlled. For example, preferably, the water in the container in which the substrate including the resin composition layer is reformed is removed or the amount of water in the sulfur trioxide-containing gas used is controlled. The amount of water in the reaction vessel can be controlled using, for example, a polymer thin film-type dew indicator. The amount of water in the container can be controlled by tracking the dew point or amount of water of substituted gas discharged from the container. The desired dew point is preferably −50° C. or less and more preferably −60° C. or less.

In the present invention, immediately after the contact, an aftertreatment is preferably performed to remove sulfur trioxide or sulfuric acid left on the surface. Examples of the aftertreatment include washing with water and a treatment performed using alkali solutions such as sodium bicarbonate water and lime water. After the substrate is washed using alkali solutions, the substrate is preferably washed using ion-exchanged water having a temperature of 10° C. or more. Ammonium ions, sodium ions, copper ions, silver ions, and the like are preferred as alkali ion components of the alkali solutions.

In the present invention, hydrophilization treatment can be selectively performed by masking a portion where no surface treatment is required. A publicly known method is employed as the masking method. Examples of the masking method include masking using an adhesive film, sheet, or tape made of resin or paper or adhesive metal foil; masking performed by applying a paint containing a UV- or electron beam-curable paint; masking using a resist material; and masking performed by physical shielding.

Through the steps described above, the surface-treated substrate of the present invention is obtained. In the case where a flexible sheet is used as the substrate and the sheet is applied as a decorative sheet or a sheet for molding, an adhesive layer or a gluey layer is preferably formed by a coating method on the surface opposite the surface treated. The adhesive layer or the gluey layer is provided in order to increase the adhesive strength with an adherend. Therefore, any of an adhesive and a gluing agent, that is, any agent composed of a material that adheres to a resin film and an adherend can be suitably selected.

Examples of the adhesive include synthetic rubbers and crystalline polymers such as acrylic resin, urethane resin, urethane-modified polyester resin, polyester resin, epoxy resin, ethylene-vinyl acetate copolymer resin (EVA), vinyl chloride resin, vinyl chloride-vinyl acetate copolymer resin, natural rubber, SBR, NBR, and silicone rubber. A solvent or solventless type adhesive can be used.

Any gluing agent may be used as long as the gluing agent has tackiness at the thermoforming temperature. Examples of the gluing agent include solvent type gluing agents such as acrylic resin, isobutylene rubber resin, styrene-butadiene rubber resin, isoprene rubber resin, natural rubber resin, and silicone resin; and solventless type gluing agents such as acrylic emulsion resin, styrene-butadiene latex resin, natural rubber latex resin, styrene-isoprene copolymer resin, styrene-butadiene copolymer resin, styrene-ethylene-butylene copolymer resin, ethylene-vinyl acetate resin, polyvinyl alcohol, polyacrylamide, and polyvinyl methyl ether.

### (Protective Sheet for Solar Cells)

As described above, the surface-treated substrate of the present invention having a sheet shape can be directly used as a light-receiving-side protective sheet for solar cells. Preferably, the substrate is composed of plastic or glass and includes the adhesive layer or the gluey layer.

### (Solar Cell Module)

There is described a specific exemplary embodiment of a solar cell module that uses the light-receiving-side protective sheet for solar cells according to the present invention. Note that the present invention obviously includes various embodiments that are not described herein.

A solar cell module is obtained by sequentially stacking a light-receiving-side protective sheet for solar cells, a first sealing member, a group of solar cells, a second sealing member, and a protective sheet for solar cells. The light-receiving-side protective sheet for solar cells is stacked so that a substrate (if an adhesive layer or a gluey layer is formed on the substrate, the adhesive layer or the gluey layer) of the protective sheet and the first sealing member are joined to each other, that is, so that a surface on the surface-treated side of the surface-treated substrate of the present invention is an outermost layer.

The first sealing member and the second sealing member are disposed between the light-receiving-side protective sheet for solar cells according to the present invention and the protective sheet for cells to seal the group of solar cells. The first sealing member and the second sealing member can be composed of a translucent resin such as ethylene-vinyl acetate copolymer (referred to as EVA), EEA, PVB, silicon, urethane, acrylic, or epoxy. The first sealing member and the second sealing member contain a crosslinking agent such as a peroxide. Therefore, by heating the first sealing member and the second sealing member to a certain crosslinking temperature or higher, they are softened and then crosslinking is initiated. As a result, the components are temporarily bonded to each other.

The group of solar cells include a plurality of solar cells and wiring members. The plurality of solar cells are electrically connected to each other through the wiring members.

After that, the first sealing member and the second sealing member laminated using a laminating machine are fully cured by heating, whereby a solar cell module can be obtained.

### EXAMPLES

The present invention will now be specifically described based on Examples and Comparative Examples. In Examples, “part” and “%” are on a mass basis unless otherwise specified.

### Synthesis Example 1

### Synthesis Example of Polysiloxane

There were prepared 415 parts of methyltrimethoxysilane (MTMS) and 756 parts of 3-methacryloyloxypropyltrimethoxysilane (MPTS) in a reactor including a stirrer, a thermometer, a dropping funnel, a cooling tube, and a nitrogen gas inlet. They were heated to 60° C. while being stirred under the ventilation of nitrogen gas. Subsequently, a mixture of 0.1 parts of “A-3” [isopropyl acid phosphate available from Sakai Chemical Industry Co., Ltd.] and 121 parts of deionized water was added dropwise thereto for five minutes. After the dropwise addition, the temperature in the reactor was increased to 80° C. and stirring was performed for four hours to cause a hydrolysis condensation reaction. Thus, a reaction product was obtained.

Methanol and water contained in the obtained reaction product were removed at 40 to 60° C. at a reduced pressure of 1 to 30 kilopascals (kPa) to obtain 1000 parts of polysiloxane (a1-1) having a number-average molecular weight of 1000 and an effective content of 75.0%.

Herein, the “effective content” is a value obtained by dividing the theoretical yield (parts by weight) in the case where all methoxy groups of a silane monomer used were subjected to a hydrolysis condensation reaction by the actual yield (parts by weight) after the hydrolysis condensation reaction. In other words, the “effective content” is calculated from the formula of [theoretical yield (parts by weight) in the case where all methoxy groups of a silane monomer were subjected to a hydrolysis condensation reaction/actual yield (parts by weight) after the hydrolysis condensation reaction].

### Synthesis Example 2

### Synthesis Example of Composite Resin (A)

There were prepared 20.1 parts of phenyltrimethoxysilane (PTMS), 24.4 parts of dimethyldimethoxysilane (DMDMS), and 107.7 parts of n-butyl acetate in the same reactor as that of Synthesis Example 1. They were heated to 80° C. while being stirred under the ventilation of nitrogen gas. Subsequently, a mixture of 62.1 parts of styrene monomer, 15 parts of butyl acrylate (BA), 40.5 parts of methyl methacrylate (MMA), 27.9 parts of 2-hydroxyethyl methacrylate (HEMA), 4.5 parts of MPTS, 15 parts of n-butyl acetate, and 15 parts of tert-butylperoxy-2-ethylhexanoate (TBPEH) was added dropwise to the reactor for four hours while being stirred at the same temperature under the ventilation of nitrogen gas. After stirring was further performed at that temperature for two hours, a mixture of 0.05 parts of “A-3” and 12.8 parts of deionized water was added dropwise to the reactor for five minutes, and stirring was performed at that temperature for four hours to proceed a hydrolysis condensation reaction of PTMS, DMDMS, and MPTS. A ¹H-NMR analysis of the reaction product found that almost 100% of the trimethoxysilyl group of the silane monomer in the reactor was hydrolyzed. Next, by performing stirring at that temperature for ten hours, a reaction product having a residual amount of TBPEH of 0.1% or less was obtained. The residual amount of TBPEH was measured by iodometry.

Subsequently, 162.5 parts of the polysiloxane (a1-1) obtained in Synthesis Example 1 was added to the reaction product. After stirring was performed for five minutes, 27.5 parts of deionized water was added thereto and stirring was performed at 80° C. for four hours to cause a hydrolysis condensation reaction between the reaction product and the polysiloxane. The resultant reaction product was distilled at a reduced pressure of 10 to 300 kPa at 40 to 60° C. for two hours, whereby generated methanol and water were removed. Next, 150 parts of methyl ethyl ketone (MEK) and 27.3 parts of n-butyl acetate were added thereto to obtain 600 parts of composite resin (A-1) having a non-volatile content of 50.0% and including a polysiloxane segment and a vinyl polymer segment.

### Synthesis Example 3

### As Above

There were prepared 20.1 parts of phenyltrimethoxysilane (PTMS), 24.4 parts of dimethyldimethoxysilane (DMDMS), and 107.7 parts of n-butyl acetate in the same reactor as that of Synthesis Example 1. They were heated to 80° C. while being stirred under the ventilation of nitrogen gas. Subsequently, a mixture of 15 parts of methyl methacrylate (MMA), 45 parts of n-butyl methacrylate (BMA), 39 parts of 2-ethylhexyl methacrylate (EHMA), 1.5 parts of acrylic acid (AA), 4.5 parts of MPTS, 45 parts of 2-hydroxyethyl methacrylate (HEMA), 15 parts of n-butyl acetate, and 15 parts of tert-butylperoxy-2-ethylhexanoate (TBPEH) was added dropwise to the reactor for four hours while being stirred at the same temperature under the ventilation of nitrogen gas. After stirring was further performed at that temperature for two hours, a mixture of 0.05 parts of “A-3” and 12.8 parts of deionized water was added dropwise to the reactor for five minutes, and stirring was performed at that temperature for four hours to proceed a hydrolysis condensation reaction of PTMS, DMDMS, and MPTS. A ¹H-NMR analysis of the reaction product found that almost 100% of the trimethoxysilyl group of the silane monomer in the reactor was hydrolyzed. Next, by performing stirring at that temperature for ten hours, a reaction product having a residual amount of TBPEH of 0.1% or less was obtained. The residual amount of TBPEH was measured by iodometry.

Subsequently, 162.5 parts of the polysiloxane (a1-1) obtained in Synthesis Example 1 was added to the reaction product. After stirring was performed for five minutes, 27.5 parts of deionized water was added thereto and stirring was performed at 80° C. for four hours to cause a hydrolysis condensation reaction between the reaction product and the polysiloxane. The resultant reaction product was distilled at a reduced pressure of 10 to 300 kPa at 40 to 60° C. for two hours, whereby generated methanol and water were removed. Next, 150 parts of methyl ethyl ketone (MEK) and 27.3 parts of n-butyl acetate were added thereto to obtain 600 parts of composite resin (A-2) having a non-volatile content of 50.0% and including a polysiloxane segment and a vinyl polymer segment.

### Formulation Examples 1 to 2 and Comparative Formulation Examples 1 to 4

Clear paints (P-1) to (P-4) and comparative clear paints (CP-1) to (CP-3) were prepared based on the composition shown in Table 1.

TABLE 1

| | Name of | | | | | | | |
|---|---|---|---|---|---|---|---|---|
| Table 1 | compound | F. E. 1 | F. E. 2 | F. E. 3 | F. E. 4 | C. E. 1 | C. E. 2 | C. E. 3 |
| Composite resin | A-1 | 15 | 19 | 6.6 | | | | |
| | A-2 | | | | 7 | 15 | | |
| Acrylic styrene | A802 | | | | 20 | | 24 | |
| St-containing UV resin | C7-164 | | | | | | | 32 |
| Polyisocyanate | D-110N | 1.6 | 4.6 | 7.2 | 7.9 | 5.7 | 6.1 | |
| Multifunctional | PETA | 0 | 3.6 | 9 | 1.6 | 3.2 | | |
| acrylate | | | | | | | | |
| Photopolymerization | Irg-184 | 0.33 | 0.56 | 0.51 | 0.22 | 0.46 | | |
| initiator | | | | | | | | |
| Ultraviolet absorber | Ti-400 | 0.12 | 0.21 | 0.19 | 0.23 | 0.17 | 0.24 | 0.32 |
| Light stabilizer | Ti-123 | 0.08 | 0.14 | 0.13 | 0.15 | 0.11 | 0.12 | 0.16 |
| Silicon content in solid | | 41% | 28% | 10% | 9% | 25% | 0% | 0% |
| Styrene content in | | 15% | 10% | 4% | 19% | 0% | 28% | 21% |
| solid | | | | | | | | |
| Name of paint | | P-1 | P-2 | P-3 | P-4 | CP-1 | CP-2 | CP-3 |

F.E.: Formulation Example
C.E.: Comparative Formulation Example
A802: ACRYDIC A802 [acrylic resin available from DIC Corporation]
C7-164: UNIDIC C7-164 [ultraviolet curable resin available from DIC Corporation]
D-110N: TAKENATE D-110N [polyisocyanate available from Mitsui Chemicals Polyurethanes, Inc]
PETA: pentaerythritol triacrylate
I-184: Irgacure 184 [photopolymerization initiator available from Ciba Japan KK]
Ti-400: TINUVIN 400 [hydroxyphenyltriazine-based ultraviolet absorber available from Ciba Japan KK]
Ti-123: TINUVIN 123 [hindered amine-based light stabilizer (HALS) available from Ciba Japan KK]

### Examples 1 to 4 and Comparative Examples 1 to 3

The clear paints (P-1) to (P-4) and comparative clear paints (CP-1) to (CP-3) prepared based on the composition shown in Table 1 were each applied on COSMO SHINE A4300 [PET film available from TOYOBO CO., LTD.] having a size of 210 mm×295 mm×0.075 mm to form a resin composition layer with a dry thickness of 20 μm.

### (Ultraviolet Curing)

The film including the resin composition layer was dried at 80° C. for 4 minutes and then the resin composition layer was cured by being irradiated with ultraviolet rays at a radiation dose of about 1000 mJ using a mercury lamp with a lamp output of 1 kW.

### (Heat Curing)

The film including the resin composition layer was left to stand at 40° C. for 3 days to cure the resin composition layer.

### (Contact Concentration of Sulfur Trioxide-Containing Gas)

The resultant film including the resin composition layer was inserted into a stainless container for contact with sulfur trioxide-containing gas that has an internal volume of 300 L and was heated to 45° C., and the film was fixed. The lid of the container was closed and sulfur trioxide-containing gas was brought into contact with the film at a gas concentration of 1.2% by volume at a dew point of dilution gas of −60° C. for 2.5 minutes. The film was then washed with ion-exchanged water at 50° C. for 5 minutes and 24 hours and the following physical properties were evaluated.

### <Method for Evaluating Physical Properties>

### (Antifouling Property: Initial Oil Contamination Resistance)

A pseudo-oil contaminant (mixture of olive oil, oleic acid, and oil red) was dropped onto the surface of the cured material layer in an amount of 0.2 ml and left to stand for 60 seconds. The film was vertically put into water having a temperature of 35 to 38° C. and the time until the pseudo-oil contaminant came off was measured. The shorter the time until the oil contaminant came off was, the higher the oil contamination resistance was. If the oil contaminant did not come off within 10 minutes, “x” was given.

(Durability: Oil Contamination Resistance after Boiling Test)

The film including the cured material layer was put into hot water having a temperature of 80° C. and left to stand for 100 hours. The film was taken out and then dried at 25° C. for 8 hours. With this test piece, a test for oil contamination resistance was performed.

(Durability: Oil Contamination Resistance after Swabbing with Acetone)

The surface of the cured material layer was rubbed with absorbent cotton impregnated with 1 ml of acetone five times. Subsequently, a test for oil contamination resistance was performed.

### (Heating and Pressurizing Test)

After the film including the cured material layer was held using a die at 145° C. at a surface pressure of 100 kg/cm² for 360 seconds, the number of cracks generated per 100 cm² was counted. If countless cracks were generated, “x” was given. Table 2 shows the results.

TABLE 2

| Table 2 | | Ex. 1 | Ex. 2 | Ex. 3 | Ex. 4 | C. E. 1 | C. E. 2 | C. E. 3 |
|---|---|---|---|---|---|---|---|---|
| Curing condition of paint | | UV | UV | UV | UV | UV | Heat | UV |
| | | Heat | Heat | Heat | Heat | Heat | | |
| Substrate | | PET | PET | PET | PET | PET | PET | PET |
| | | sheet | sheet | sheet | sheet | sheet | sheet | sheet |
| Initial oil contamination | (sec) | 10 | 7 | 22 | 28 | 25 | 18 | 19 |
| resistance | | | | | | | | |
| Oil contamination | (sec) | 22 | 21 | 52 | 27 | 112 | 21 | 92 |
| resistance after boiling | | | | | | | | |
| test | | | | | | | | |
| Oil contamination | (sec) | 12 | 8 | 23 | 95 | 381 | x | 80 |
| resistance after | | | | | | | | |
| swabbing with acetone | | | | | | | | |
| Cracks after molding | (cracks) | 0 | 0 | 0 | 3 | 0 | x | 0 |
| Oil contamination | (sec) | 25 | 27 | 81 | 26 | 326 | 22 | 212 |
| resistance after molding | | | | | | | | |

Ex: Example
C.E.: Comparative Example

As a result, the films of Examples 1 and 2 surface-treated through sulfonation each had a surface with a good antifouling property and high durability of the antifouling property. In these films, the properties were not degraded even after the boiling test and the swabbing with acetone and no cracks were generated after the heating and pressurizing test. The film of Example 3 includes a slightly smaller number of polysiloxane bonds and benzene rings, and the time until an oil contaminant came off took slightly longer. The film of Example 4 includes a siloxane resin having no benzene ring and an acrylic-styrene resin in a mixed manner, and the time until an oil contaminant came off took slightly longer and streaks of cracks were formed in the surface.

The film of Comparative Example 1 includes polysiloxane bonds but not benzene rings, and the durability of antifouling property was not achieved at all and the film was significantly degraded. The film of Comparative Example 2 includes only an acrylic-styrene resin, and the antifouling property after the swabbing with acetone was lost and cracks were formed after the molding. The film of Comparative Example 3 includes a UV curable resin having a benzene ring, and the antifouling property was degraded after the boiling test or the swabbing with acetone because the film did not include polysiloxane bonds.

### Example 5

The film surface-treated through sulfonation in Example 1 was used as a light-receiving-side protective sheet for solar cells of a solar cell module, and the generation efficiency after outdoor exposure was evaluated.

### (Method for Producing Solar Cell Module)

### (Preparation of Sealing Member)

To prepare a composition for sealing member for solar cells, 100 parts of EVA (ethylene-vinyl acetate copolymer (the content of vinyl acetate: 28% by weight)) and 1.3 parts of 2,5-dimethyl-2,5-di(2-ethylhexanoylperoxy)hexane serving as a crosslinking agent were kneaded using a roll mill at 70° C. The composition for sealing member for solar cells was calendered at 70° C. and cooled to prepare a sealing member for solar cells (thickness: 0.6 mm).

### (Production of Backstrate Solar Cell Module)

A hot plate of a laminating machine (available from Nisshinbo Mechatronics Inc.) was adjusted to 150° C. An aluminum plate, the sealing member for solar cells, a polycrystalline silicon solar cell, the sealing member for solar cells, and a photocatalyst-supporting sheet (1) obtained in Example 1 as the light-receiving-side protective sheet for solar cells were stacked on the hot plate in that order. A lid of the laminating machine was closed, and degassing was performed for three minutes and then pressing was performed for eight minutes. After the laminated body was held in the laminating machine for ten minutes, it was taken out. Thus, a backstrate solar cell module (F-1) was obtained.

### (Evaluation of Generation Efficiency)

The generation efficiency (%) of the solar cell module was measured using Solar Simulator available from WACOM ELECTRIC CO., LTD. at a module temperature of 25° C. at a radiant intensity of 1 kW/m² at a spectral distribution of AM 1.5 G.

Herein, there was shown the difference between the generation efficiency (%) of a solar cell module subjected to outdoor exposure for one year at Sakai Plant of DIC Corporation located in the industrial area in Takaishi, Osaka and the generation efficiency (%) of an untested module. A larger difference indicates higher degree of contamination on the surface of the film surface-treated through sulfonation.

Difference in generation efficiency=initial generation efficiency (%)−generation efficiency (%) after accelerated weathering test [Math. 1]

### Comparative Example 4

A solar cell module HF-1 was obtained by the same method as in Example 5, except that the film surface-treated through sulfonation in Comparative Example 1 was used instead of the film surface-treated through sulfonation in Example 1.

Table 3 shows the module names and the differences in generation efficiency of Example 5 and Comparative Example 4.

TABLE 3
Evaluation table of physical properties in Examples

| | | Comparative |
|---|---|---|
| | Example 5 | Example 4 |
| Solar cell module | F-1 | HF-1 |
| Difference in generation efficiency (%) | 0.3 | 3.0 |

As a result, the solar cell module of Example 5 in which the film surface-treated through sulfonation in Example 1 was used as a light-receiving-side protective sheet for solar cells was not easily affected by soot, had a clear surface, and had substantially the same generation efficiency as that in the initial state due to the effect of preventing oil contamination. In contrast, in the solar cell module of Comparative Example 4 in which the film surface-treated through sulfonation in Comparative Example 1 was used, soot was attached to the surface of the front sheet due to poor oil contamination resistance and thus the generation efficiency was significantly decreased.

1. A substrate comprising, on a surface, a cured material layer composed of a resin composition and surface-treated with a sulfur trioxide-containing gas,
wherein the resin composition contains a composite resin (A) obtained by bonding a polysiloxane segment (a1) having a structural unit represented by general formula (1) and/or general formula (2) and a silanol group and/or a hydrolyzable silyl group to a vinyl-based polymer segment (a2) through a bond represented by general formula (3); and the vinyl-based polymer segment (a2) is an aromatic vinyl-based polymer segment obtained by polymerizing or copolymerizing an aromatic vinyl-based monomer selected from the group consisting of styrene, p-tert-butylstyrene, α-methylstyrene, and vinyltoluene: 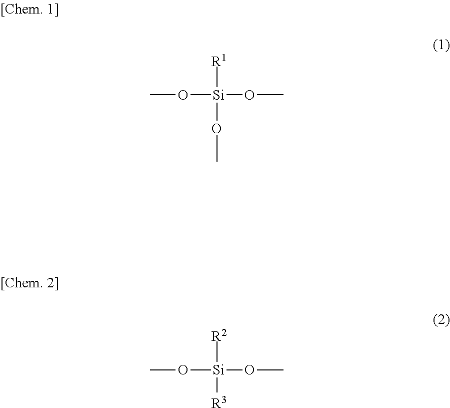
(wherein in the general formulas (1) and (2), R¹, R², and R³ are each independently a group having a polymerizable double bond selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms), 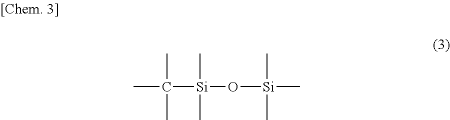
(wherein in the general formula (3), a carbon atom constitutes a part of the vinyl-based polymer segment (a2) and a silicon atom bonded to only an oxygen atom constitutes a part of the polysiloxane segment (a1)).

2. The substrate comprising, on a surface, a cured material layer composed of a resin composition and surface-treated according to claim 1, wherein at least one of R¹, R², and R³ in the general formulas (1) and (2) is the group having a polymerizable double bond.

3. The substrate comprising, on a surface, a cured material layer composed of a resin composition and surface-treated according to claim 1, wherein the vinyl-based polymer segment (a2) has an alcoholic hydroxyl group and the resin composition contains polyisocyanate (B).

4. (canceled)

5. (canceled)

6. A light-receiving-side protective sheet for solar cells obtained by forming a cured material layer composed of a resin composition on a surface of a sheet-shaped substrate and then treating a surface of the cured material layer composed of the resin composition with a sulfur trioxide-containing gas,
wherein the resin composition contains a composite resin (A) obtained by bonding a polysiloxane segment (a1) having a structural unit represented by general formula (1) and/or general formula (2) and a silanol group and/or a hydrolyzable silyl group to a vinyl-based polymer segment (a2) through a bond represented by general formula (3); and the vinyl-based polymer segment (a2) is an aromatic vinyl-based polymer segment obtained by polymerizing or copolymerizing an aromatic vinyl-based monomer selected from the group consisting of styrene, p-tert-butylstyrene, α-methylstyrene, and vinyltoluene: 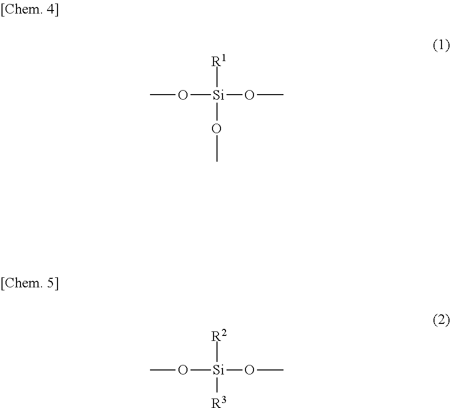
(wherein in the general formulas (1) and (2), R¹, R², and R³ are each independently a group having a polymerizable double bond selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms), 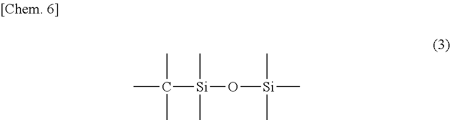
(wherein in the general formula (3), a carbon atom constitutes a part of the vinyl-based polymer segment (a2) and a silicon atom bonded to only an oxygen atom constitutes a part of the polysiloxane segment (a1)).

7. A solar cell module comprising the light-receiving-side protective sheet for solar cells according to claim 6, wherein the light-receiving-side protective sheet for solar cells is disposed on a front surface on a light-receiving side of the solar cell module so that the cured material layer is an outermost surface layer.

8. A method for surface-treating a cured material layer composed of a resin composition and formed on a surface of a substrate, the method comprising:
a step (1) of forming, on a surface of a substrate, a cured material layer composed of a resin composition containing a composite resin (A), the composite resin (A) being obtained by bonding a polysiloxane segment (a1) having a structural unit represented by general formula (1) and/or general formula (2) and a silanol group and/or a hydrolyzable silyl group to a vinyl-based polymer segment (a2) through a bond represented by general formula (3), the vinyl-based polymer segment (a2) being an aromatic vinyl-based polymer segment obtained by polymerizing or copolymerizing an aromatic vinyl-based monomer selected from the group consisting of styrene, p-tert-butylstyrene, α-methylstyrene, and vinyltoluene; and
a step (2) of bringing a sulfur trioxide-containing gas into contact with the cured material layer composed of the resin composition: 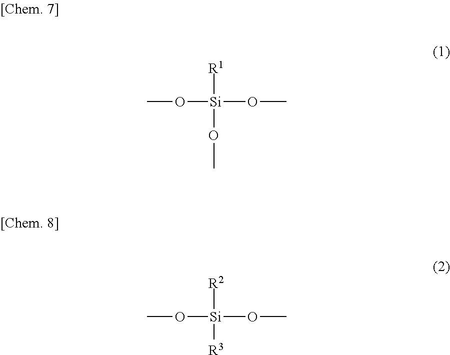
(wherein in the general formulas (1) and (2), R¹, R², and R³ are each independently a group having a polymerizable double bond selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms), 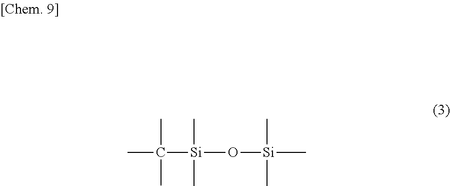
(wherein in the general formula (3), a carbon atom constitutes a part of the vinyl-based polymer segment (a2) and a silicon atom bonded to only an oxygen atom constitutes a part of the polysiloxane segment (a1)).

9. The substrate comprising, on a surface, a cured material layer composed of a resin composition and surface-treated according to claim 2, wherein the vinyl-based polymer segment (a2) has an alcoholic hydroxyl group and the resin composition contains polyisocyanate (B).
